(19) United States
(12) Patent Application Publication
(10) Pub. No.: US 2016/0020096 A1
(43) Pub. Date: Jan. 21, 2016

(54) Manufacture Method Of Low Temperature Poly Silicon, Manufacturing Method Of TFT Substrate Utilizing The Method, And TFT Substrate Structure

(71) Applicant: SHENZHEN CHINA STAR OPTOELECTRONICS TECHNOLOGY CO., LTD., Shenzhen, Guangdong (CN)

(72) Inventor: Xiaoxing ZHANG, Shenzhen, Guangdong (CN)

(73) Assignee: SHENZHEN CHINA STAR OPTOELECTRONICS TECHNOLOGY CO., LTD., Shenzhen, Guangdong (CN)

(21) Appl. No.: 14/398,448

(22) PCT Filed: Aug. 15, 2014
(86) PCT No.: PCT/CN2014/084443

§ 371 Date: Oct. 31, 2014

(30) Foreign Application Priority Data
Jul. 10, 2014 (CN) 201410329164.9

(51) Int. Cl. H01L 21/02; H01L 27/12

(52) U.S. Cl. CPC H01L 21/02675; H01L 21/02488; H01L 21/02532; H01L 21/02595; H01L 27/1222; H01L 27/1274

(57) ABSTRACT

The present invention provides a manufacture method of Low Temperature Poly Silicon, a manufacture method of a TFT substrate utilizing the method and a TFT substrate structure. The manufacture method of Low Temperature Poly Silicon comprises steps of: step 1, providing a substrate (1); step 2, depositing a buffer layer (2) on the substrate (1); step 3, patterning the buffer layer (2) to form a convex part (21) and a concave part (23) having different thicknesses; step 4, depositing an amorphous silicon layer (3) on the buffer layer (2) comprising the convex part (21) and the concave part (23); step 5, implementing a pretreatment of an excimer laser anneal to the amorphous silicon layer (3); step 6, implementing the excimer laser anneal to the amorphous silicon layer (3), and a laser beam scans an entire surface of the amorphous silicon layer (3) to melt the amorphous silicon layer (3) to recrystallize as a poly silicon layer (4). The method is capable of effectively controlling the locations and the directions of the recrystallization.

### FIELD OF THE INVENTION

The present invention relates to a skill field of display, and more particularly to a manufacture method of Low Temperature Poly Silicon, a manufacture method of TFT substrate utilizing the method and a TFT substrate structure.

### BACKGROUND OF THE INVENTION

With the development of the flat panel displays, the panels with higher resolutions and lower power consumption are constantly required. Because the Low Temperature Poly-Silicon (LTPS) possess high electron mobility, the industry attaches importance to it in the Liquid Crystal Display (LCD) and Organic Light Emitting Diode (OLED) skill fields. The LPTS is considered as an important material for realizing low cost, full color flat panel displays. For a flat panel display, the Low Temperature Poly-Silicon has many advantages such as high resolution, fast response rate, high brightness, high aperture ratio, low power consumption and etc. Meanwhile, the Low Temperature Poly-Silicon can be produced under low temperature environment and with the capability of manufacturing the C-MOS (Complementary Metal Oxide Semiconductor) circuit, the Low Temperature Poly-Silicon is widely discussed for meeting the requirement of high resolution and low power consumption.

The Low Temperature Poly-Silicon (LTPS) is a branch of Poly-Silicon technology. The arrangement of the molecule structure of the Poly-Silicon in a crystal grain is regular and directional. Therefore, the electron mobility is 200-300 times of the amorphous silicon (a-Si) which is arranged in disorder the response rate of the flat panel display can be enormously promoted. In the initial developing stages of the Poly-Silicon technology, A Laser anneal process, which is a high temperature oxidation process is necessary for transferring the structure of the glass substrate from amorphous silicon (a-Si) into Poly-Silicon. Then, High Temperature Poly-Silicon (HTPS) can be obtained. In this moment, the temperature of the glass substrate can reach over 1000 degree C. In comparison with the traditional High Temperature Poly-Silicon, the laser exposure process is still required for the Low Temperature Poly-Silicon, thought. Nevertheless, an Excimer laser is employed as being the heat source. After the laser is conducted through the transmission system, a laser beam with uniformly distributed energy is projected on the glass substrate with amorphous silicon structure. After the glass substrate with amorphous silicon structure absorbs the energy of the Excimer laser, the glass substrate is then transferred into Poly-Silicon structure substrate. The whole process is accomplished under 600 degree C. Any normal glass substrates can bare such temperature which enormously reduces the manufacture cost. Beside reduction of the manufacture cost, the Low Temperature Poly-Silicon technology further provides more merits: higher electron mobility, better stability.

At present, several methods for producing the Low Temperature Poly-Silicon can be illustrated, such as Solid Phase Crystallization (SPC), Solid Phase Crystallization (SPC) and Excimer laser anneal (ELA), among which Excimer laser anneal (ELA) is the most widely used and relatively developed method nowadays. It utilizes the transient pulses of the excimer laser to irradiate the surface of the amorphous silicon to melt and recrystallize the amorphous silicon. However, the simple ELA crystallization technology cannot effectively control the uniformity of the crystal lattices and the crystallization direction of the crystal lattices. Therefore, the crystallization on the entire substrate is not uniform enough and causes the uniform display effect.

As shown from FIGS. 1-5, a manufacture method of Low Temperature Poly Silicon and a manufacture method of a TFT substrate mainly comprises steps of: step 1, providing a glass substrate 100; step 2, forming a buffer layer 200 on the glass substrate 100, and the thickness of the buffer layer 200 is uniform; step 3, forming an amorphous silicon layer 300 on the buffer layer 200; step 4, proceeding a pretreatment of an excimer laser anneal to the amorphous silicon layer 300; step 5, proceeding the excimer laser anneal to the amorphous silicon layer 300, and the Laser is employed to scan the entire surface of the amorphous silicon layer 300 to melt and recrystallize the amorphous silicon layer 300 to form a poly silicon layer 400; step 6, proceeding a formation treatment to the poly silicon layer 400 to form a poly silicon semiconductor layer 450; step 7, sequentially forming a gate isolation layer 500, a gate 600, an isolation layer 700, a source/a drain 800 on the poly silicon semiconductor layer 450 and the source/the drain 800 is connected to the poly silicon semiconductor layer 450.

In the recrystallization of the amorphous silicon layer, the recrystallization occurs in accordance with the directions from low energy toward high energy, from low temperature to high temperature. In the aforesaid manufacture method of Low Temperature Poly Silicon and the manufacture method of a TFT substrate, the amorphous silicon layer is directly formed on the buffer layer which the thickness is uniform. During the process of Excimer laser anneal, the heated conditions of the respective areas of the amorphous silicon layer reach unanimity and no temperature gradients exist. Consequently, the start point of recrystallization and the direction of the crystal lattice are in a mess. The crystal lattice of the poly silicon layer after recrystallization is too small and too many grain boundaries appear. The distribution of the crystallization on the entire substrate is so not uniform. The electron mobility is influenced to cause the uniform display effect.

For obtaining better poly silicon, some lateral crystallization skills are proposed to expect a better control of the uniformity of the crystal lattice and the crystal orientation. For example, the crystallization arts, SLS crystallization or mask shield can be illustrated. Moreover, partial points of increasing thickness of the amorphous silicon layer for the following ELA crystallization also can be illustrated. Nevertheless, these proposed skills all require extra technology and processes and have highly restrict demands to the precision of the mask. The mass production can be quite difficult.

### SUMMARY OF THE INVENTION

An objective of the present invention is to provide a manufacture method of Low Temperature Poly Silicon capable of effectively controlling the locations and the directions of the recrystallization of the amorphous silicon layer as forming a poly silicon layer to make the distribution of the crystallization on the entire substrate more uniform.

Another objective of the present invention is to provide a manufacture method of a TFT substrate utilizing the manufacture method of Low Temperature Poly Silicon capable of effectively controlling the locations and the directions of the recrystallization of the amorphous silicon layer as forming a poly silicon layer to reduce the amount of grain boundaries in the channel area to make the distribution of the crystallization on the entire substrate more uniform for raising the performance of the TFT substrate.

Another objective of the present invention is to provide a TFT substrate structure capable of promoting electron mobility to raise the performance of the TFT substrate and to promote the display effect.

For realizing the aforesaid objective, the present invention provides a manufacture method of Low Temperature Poly Silicon, comprising steps of:

step 1, providing a substrate;

step 2, depositing a buffer layer on the substrate;

step 3, patterning the buffer layer to form a convex part and a concave part having different thicknesses;

step 4, depositing an amorphous silicon layer on the buffer layer comprising the convex part and the concave part;

step 5, implementing a pretreatment of an excimer laser anneal to the amorphous silicon layer;

step 6, implementing the excimer laser anneal to the amorphous silicon layer, and a laser beam scans an entire surface of the amorphous silicon layer to melt the amorphous silicon layer to recrystallize as a poly silicon layer.

The material of the buffer layer is SiNx, SiOx, or a combination of the SiNx and the SiOx.

An orientation of the convex part and the concave part in the step 3 is in accordance with an orientation of the laser beam and perpendicular to a scan direction of the laser beam in the step 6; the orientation of the convex part and the concave part in the step 3 corresponds to a length direction of a channel of the poly silicon semiconductor layer to be formed.

A thickness difference between the convex part and the concave part is larger than 500 A; the amorphous silicon layer melts to recrystallize as the poly silicon layer in the step 6, and the amorphous silicon layer of the concave part crystallizes first and then recrystallization occurs along a direction from the concave part to the convex part.

The present invention further provides a manufacture method of a TFT substrate utilizing the manufacture method of Low Temperature Poly Silicon, comprising steps of:

step 1, providing a substrate;

step 2, depositing a buffer layer on the substrate;

step 3, patterning the buffer layer to form a convex part and a concave part having different thicknesses;

step 4, depositing an amorphous silicon layer on the buffer layer comprising the convex part and the concave part;

step 5, implementing a pretreatment of an excimer laser anneal to the amorphous silicon layer;

step 6, implementing the excimer laser anneal to the amorphous silicon layer, and a laser beam scans an entire surface of the amorphous silicon layer to melt the amorphous silicon layer to recrystallize as a poly silicon layer;

step 7, implementing formation treatment to the poly silicon layer to form a poly silicon semiconductor layer;

step 8, sequentially forming a gate isolation layer, a gate, an isolation layer, a source/a drain on the poly silicon semiconductor layer, and the source/the drain is connected to the poly silicon semiconductor layer.

The material of the buffer layer is SiNx, SiOx, or a combination of the SiNx and the SiOx.

An orientation of the convex part and the concave part in the step 3 is in accordance with an orientation of the laser beam and perpendicular to a scan direction of the laser beam in the step 6; the orientation of the convex part and the concave part in the step 3 corresponds to a length direction of a channel of the poly silicon semiconductor layer formed in the step 7.

A thickness difference between the convex part and the concave part is larger than 500 A; the amorphous silicon layer melts to recrystallize as the poly silicon layer in the step 6, and the amorphous silicon layer of the concave part crystallizes first and then recrystallization occurs along a direction from the concave part to the convex part.

The present invention further provides a TFT substrate structure utilizing the manufacture method of a TFT substrate, comprising: a substrate, a buffer layer on the substrate, a poly silicon semiconductor layer on the buffer layer, a gate isolation layer on the poly silicon semiconductor layer and the buffer layer, a gate on the gate isolation layer, an isolation layer on the gate and the gate isolation layer and a source/a drain on the isolation layer, and the source/the drain is connected to the poly silicon semiconductor layer, wherein the buffer layer comprises the convex part and the concave part having different thicknesses.

An orientation of the convex part and the concave part corresponds to a length direction of a channel of the poly silicon semiconductor layer, and a thickness difference between the convex part and the concave part is larger than 500 A, and material of the buffer layer is SiNx, SiOx, or a combination of the SiNx and the SiOx.

The benefits of the present invention are: the manufacture method of Low Temperature Poly Silicon forms the convex part and the concave part having different thicknesses by patterning the buffer layer. In the excimer laser anneal process, the heat conservation of the convex part is better than that of the concave part. Accordingly, a temperature gradient is formed for effectively controlling the locations and the directions of the recrystallization of the amorphous silicon layer as forming a poly silicon layer to make the distribution of the crystallization on the entire substrate more uniform. The method is simple and easy for operation. The manufacture method of a TFT substrate by utilizing the manufacture method of Low Temperature Poly Silicon forms the convex part and the concave part having different thicknesses by patterning the buffer layer. In the excimer laser anneal process, the heat conservation of the convex part is better than that of the concave part. Accordingly, a temperature gradient is formed for effectively controlling the locations and the directions of the recrystallization of the amorphous silicon layer as forming a poly silicon layer to reduce the amount of grain boundaries in the channel area to make the distribution of the crystallization on the entire substrate more uniform for raising the performance of the TFT substrate. According to the substrate structure utilizing the manufacture method of a TFT substrate, the buffer layer comprises convex part and the concave part having different thicknesses. Accordingly, the locations and the directions of the crystallization during the formation of the poly silicon semiconductor layer on the buffer layer can be effectively controlled to reduce the amount of grain boundaries in the channel area to provide higher electron mobility to raise the performance of the TFT substrate and to promote the display effect.

### BRIEF DESCRIPTION OF THE DRAWINGS

In order to better understand the characteristics and technical aspect of the invention, please refer to the following detailed description of the present invention is concerned with the diagrams, however, provide reference to the accompanying drawings and description only and is not intended to be limiting of the invention.

In drawings,

FIG. 1 is a sectional diagram of step 2 of a manufacture method of Low Temperature Poly Silicon and a manufacture method of a TFT substrate according to prior art;

FIG. 2 is a sectional diagram of step 3 of a manufacture method of Low Temperature Poly Silicon and a manufacture method of a TFT substrate according to prior art;

FIG. 3 is a sectional diagram of step 5 of a manufacture method of Low Temperature Poly Silicon and a manufacture method of a TFT substrate according to prior art;

FIG. 4 is a sectional diagram of step 6 of a manufacture method of Low Temperature Poly Silicon and a manufacture method of a TFT substrate according to prior art;

FIG. 5 is a sectional diagram of step 7 of a manufacture method of Low Temperature Poly Silicon and a manufacture method of a TFT substrate according to prior art;

FIG. 6 is a flowchart of a manufacture method of Low Temperature Poly Silicon according to the present invention;

FIG. 7 is a flowchart of a manufacture method of a TFT substrate utilizing the manufacture method of Low Temperature Poly Silicon according to the present invention;

FIG. 8 is a sectional diagram of step 2 of a manufacture method of Low Temperature Poly Silicon and a manufacture method of a TFT substrate utilizing the manufacture method according to the present invention;

FIG. 9 is a sectional diagram of step 3 of a manufacture method of Low Temperature Poly Silicon and a manufacture method of a TFT substrate utilizing the manufacture method according to the present invention;

FIG. 10 is a top view diagram of step 3 of a manufacture method of Low Temperature Poly Silicon and a manufacture method of a TFT substrate utilizing the manufacture method according to the present invention;

FIG. 11 is a sectional diagram of step 4 of a manufacture method of Low Temperature Poly Silicon and a manufacture method of a TFT substrate utilizing the manufacture method according to the present invention;

FIG. 12 is a sectional diagram of step 6 of a manufacture method of Low Temperature Poly Silicon and a manufacture method of a TFT substrate utilizing the manufacture method according to the present invention;

FIG. 13 is a top view diagram of step 6 of a manufacture method of Low Temperature Poly Silicon and a manufacture method of a TFT substrate utilizing the manufacture method according to the present invention;

FIG. 14 is a sectional diagram of step 7 of a manufacture method of a TFT substrate utilizing the manufacture method of Low Temperature Poly Silicon according to the present invention;

FIG. 15 is a top view diagram of step 7 of a manufacture method of a TFT substrate utilizing the manufacture method of Low Temperature Poly Silicon according to the present invention;

FIG. 16 is a sectional diagram of step 8 of a manufacture method of a TFT substrate utilizing the manufacture method of Low Temperature Poly Silicon according to the present invention and a sectional diagram of a TFT substrate structure according to the present invention.

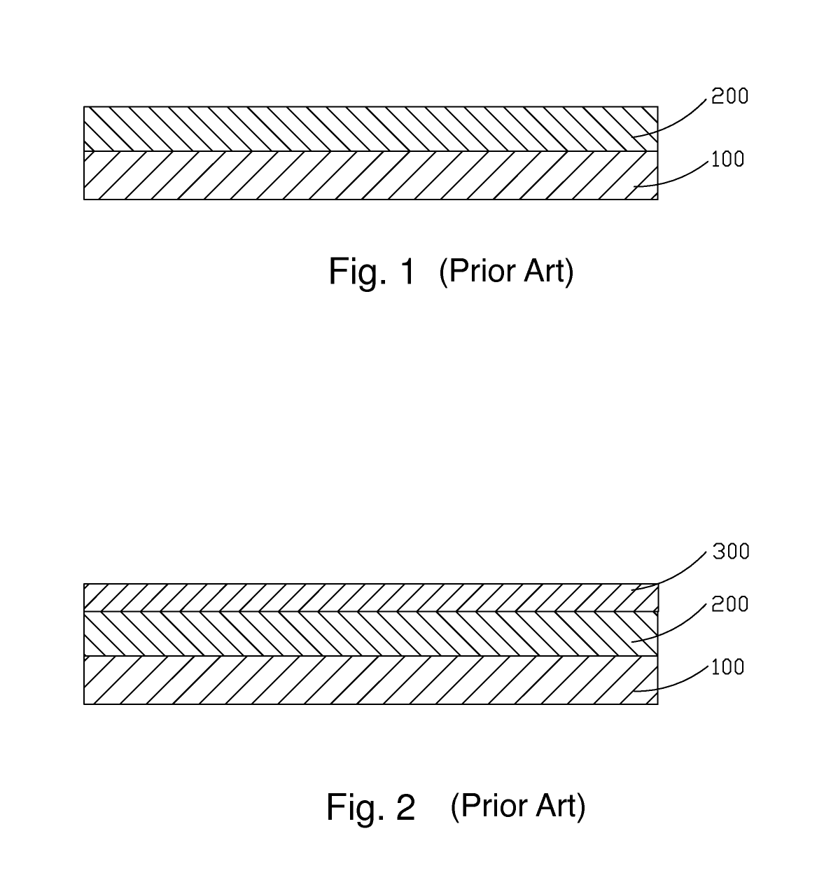

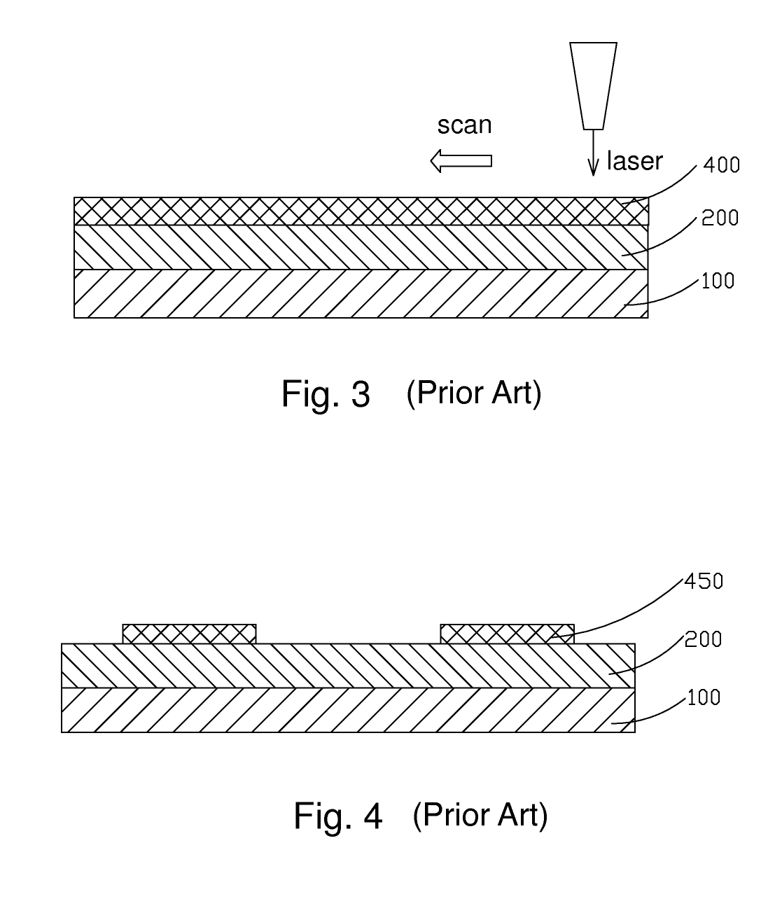

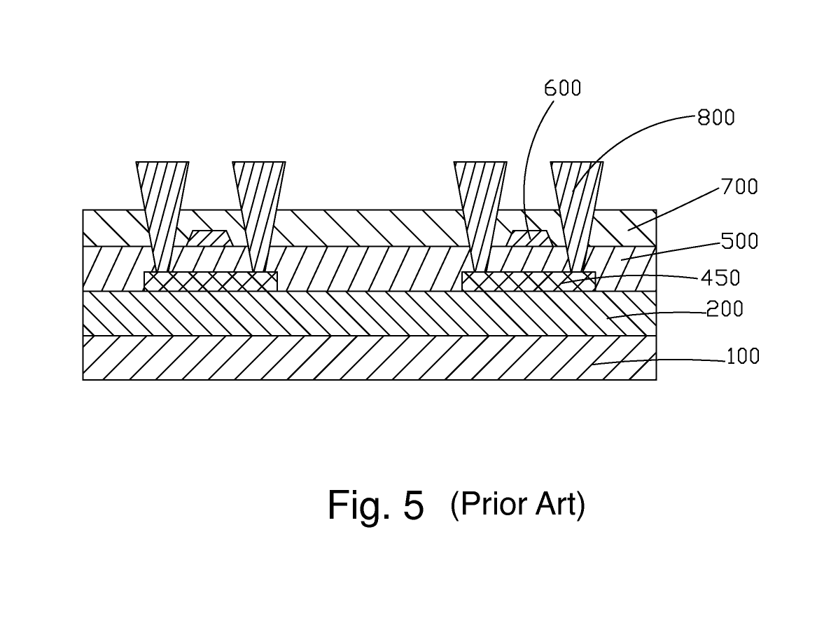

### DETAILED DESCRIPTION OF PREFERRED EMBODIMENTS

Embodiments of the present invention are described in detail with the technical matters, structural features, achieved objects, and effects with reference to the accompanying drawings as follows.

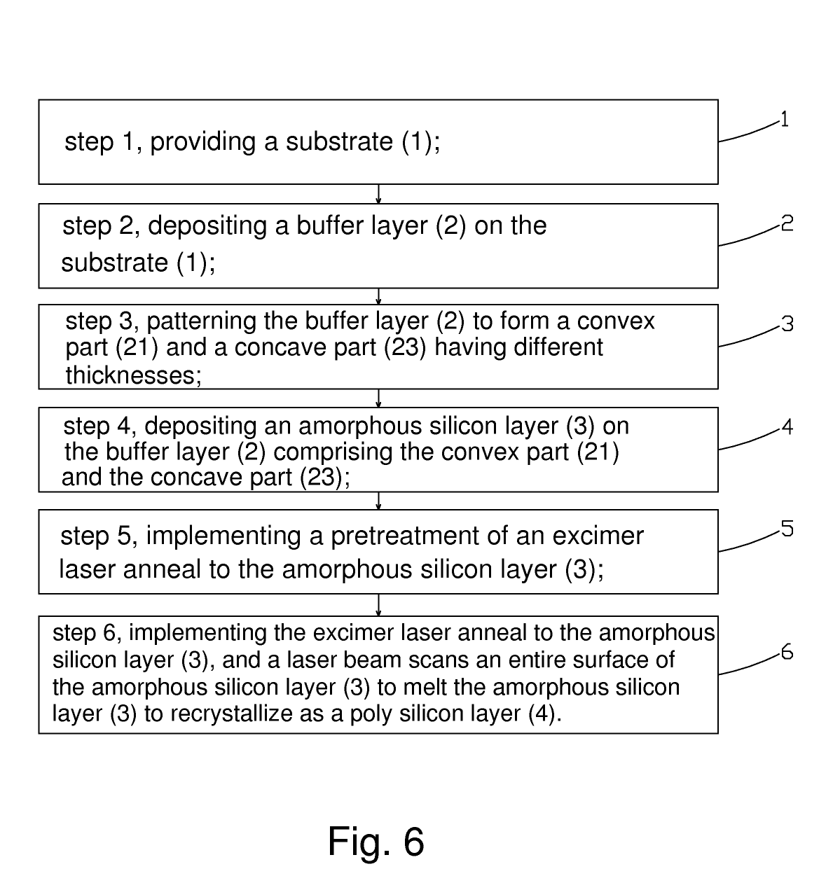

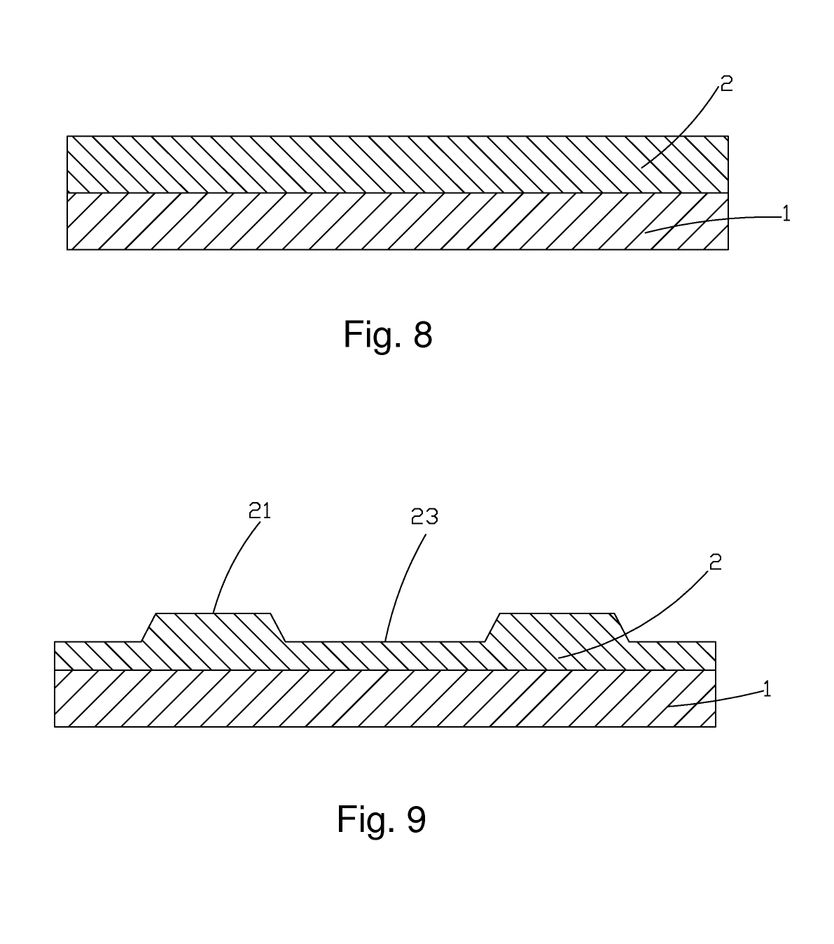

Please refer to FIG. 6 and from FIG. 8 to FIG. 13. The present invention provides a manufacture method of Low Temperature Poly Silicon, comprising steps of:

step 1, providing a substrate 1.

The substrate 1 is a transparent substrate. Preferably, the substrate 1 is a substrate 1 is a glass substrate.

step 2, depositing a buffer layer 2 on the substrate 1.

As shown in FIG. 8, the thickness of the buffer layer 2 deposited in the step 2 is uniform. The material of the buffer layer 2 is SiNx, SiOx, or a combination of the SiNx and the SiOx.

step 3, patterning the buffer layer 2 to form a convex part 21 and a concave part 23 having different thicknesses.

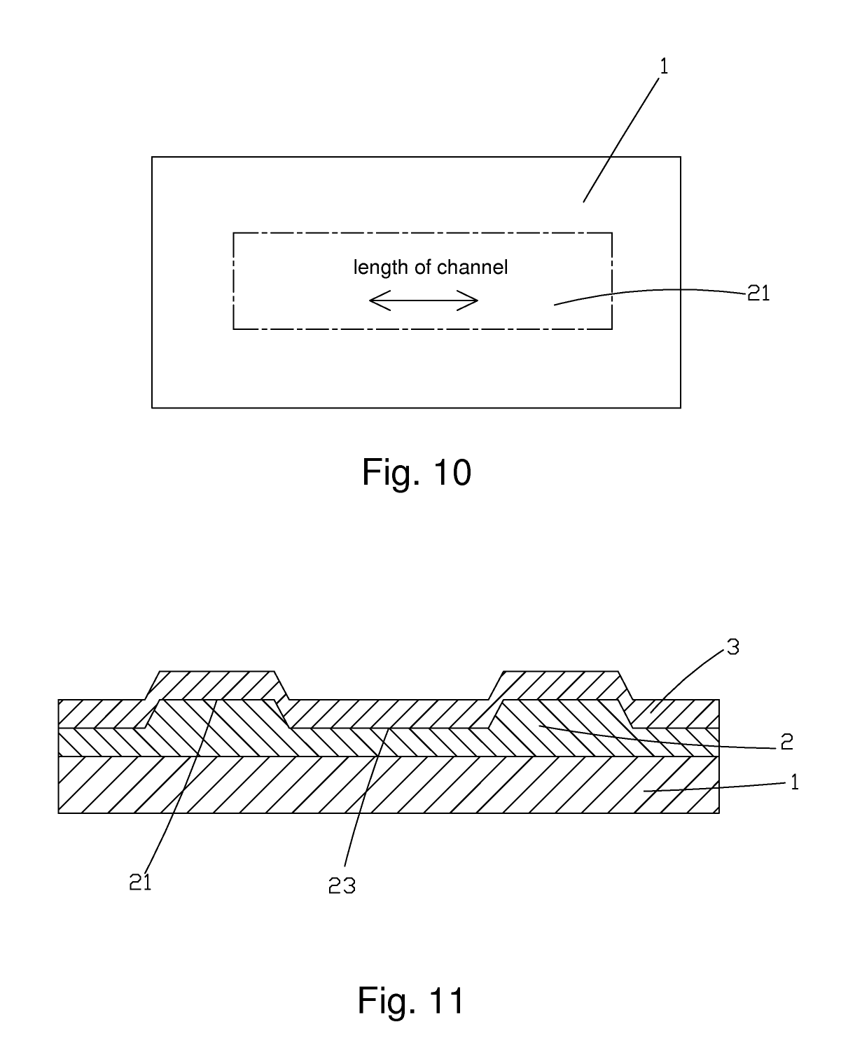

As shown in FIG. 9 and FIG. 10, a thickness difference exists between the convex part 21 and the concave part 23 and specifically the thickness difference is larger than 500 A. Significantly, an orientation of the convex part 21 and the concave part 23 in the step 3 is in accordance with an orientation of the laser beam and perpendicular to a scan direction of the laser beam in the following step 6, moreover, it corresponds to a length direction of a channel of the poly silicon semiconductor layer to be formed.

step 4, depositing an amorphous silicon layer 3 on the buffer layer 2 comprising the convex part 21 and the concave part 23.

As shown in FIG. 11, in the step 4, a thickness of the amorphous silicon layer 3 in the convex part 21 is consistent with a thickness of the amorphous silicon layer 3 in the concave part 23.

step 5, implementing a pretreatment of an excimer laser anneal to the amorphous silicon layer 3.

step 6, implementing the excimer laser anneal to the amorphous silicon layer 3, and a laser beam scans an entire surface of the amorphous silicon layer 3 to melt the amorphous silicon layer 3 to recrystallize as a poly silicon layer 4.

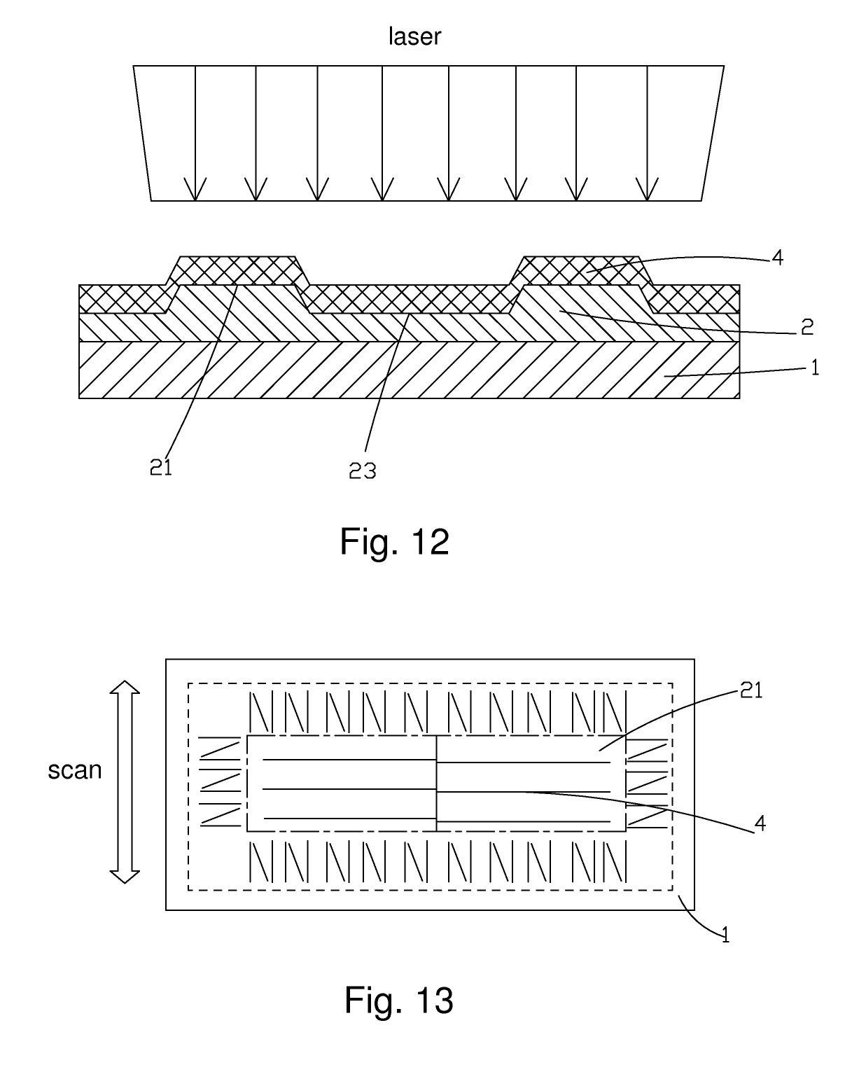

As shown in FIG. 12, FIG. 13, in the step 6, the amorphous silicon layer 3 is implemented with the excimer laser anneal process. The entire surface of the amorphous silicon layer 3 is scanned by the laser beam. The orientation of the laser beam is in accordance with the length direction of the channel of the poly silicon semiconductor layer to be formed. The scan direction of the laser beam is perpendicular to the length direction of the channel of the poly silicon semiconductor layer to be formed. The amorphous silicon layer 3 absorbs the energy of the laser beam and the temperature is raised to melt to recrystallize. Because the convex part 21 is thicker and the heat conservation is better. The temperature of the amorphous silicon layer 3 in the convex part 21 is higher and melts more completely; the concave part 23 is thinner and the heat conservation is worse. The temperature of the amorphous silicon layer 3 in the concave part 23 is relatively lower and the melting down is not so complete. Accordingly, temperature gradients exist between the convex part 21 and the concave part 23. The recrystallization of the amorphous silicon occurs in accordance with the directions from low energy toward high energy, from low temperature to high temperature. Therefore, the amorphous silicon in the concave part 23 which the temperature is relatively lower starts to crystallize, and then the recrystallization occurs along the direction from the low temperature to the high temperature, i.e. along the direction from the concave part 23 toward the convex part 21. Ultimately, the crystal lattices meet in the middle of the length direction of the channel. Accordingly, the locations and the directions of the recrystallization of the amorphous silicon layer 3 as forming a poly silicon layer 4 can be effectively controlled. The amount of grain boundaries in the channel area can be reduced to make the distribution of the crystallization on the entire substrate more uniform.

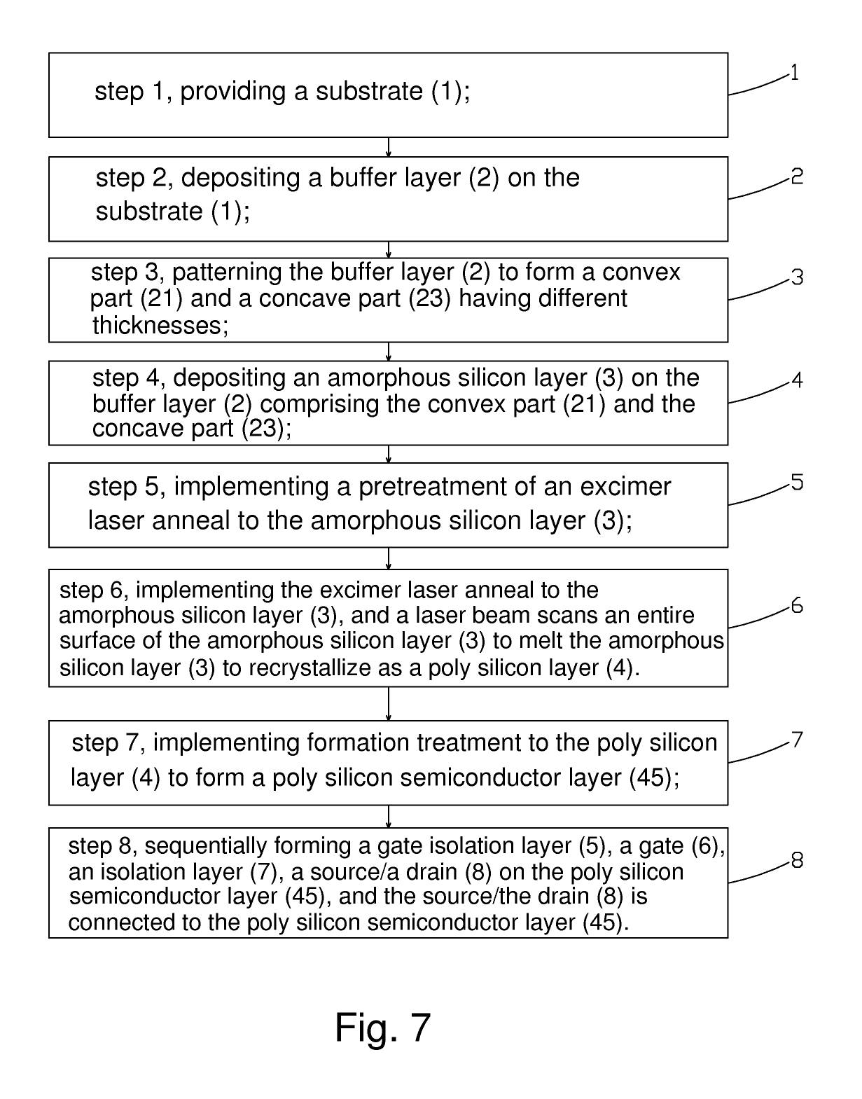

Please refer from FIG. 7 to FIG. 16. On the basis of the manufacture method of Low Temperature Poly Silicon, the present invention further provides a manufacture method of a TFT substrate utilizing the method, comprising steps of:

step 1, providing a substrate 1.

The substrate 1 is a transparent substrate. Preferably, the substrate 1 is a substrate 1 is a glass substrate.

step 2, depositing a buffer layer 2 on the substrate 1.

As shown in FIG. 8, the thickness of the buffer layer 2 deposited in the step 2 is uniform. The material of the buffer layer 2 is SiNx, SiOx, or a combination of the SiNx and the SiOx.

step 3, patterning the buffer layer 2 to form a convex part 21 and a concave part 23 having different thicknesses.

As shown in FIG. 9 and FIG. 10, a thickness difference exists between the convex part 21 and the concave part 23 and specifically the thickness difference is larger than 500 A. Significantly, an orientation of the convex part 21 and the concave part 23 in the step 3 is in accordance with an orientation of the laser beam and perpendicular to a scan direction of the laser beam in the following step 6, moreover, it corresponds to a length direction of a channel of the poly silicon semiconductor layer to be formed.

step 4, depositing an amorphous silicon layer 3 on the buffer layer 2 comprising the convex part 21 and the concave part 23.

As shown in FIG. 11, in the step 4, a thickness of the amorphous silicon layer 3 in the convex part 21 is consistent with a thickness of the amorphous silicon layer 3 in the concave part 23.

step 5, implementing a pretreatment of an excimer laser anneal to the amorphous silicon layer 3.

step 6, implementing the excimer laser anneal to the amorphous silicon layer 3, and a laser beam scans an entire surface of the amorphous silicon layer 3 to melt the amorphous silicon layer 3 to recrystallize as a poly silicon layer 4.

As shown in FIG. 12, FIG. 13, in the step 6, the amorphous silicon layer 3 is implemented with the excimer laser anneal process. The entire surface of the amorphous silicon layer 3 is scanned by the laser beam. The orientation of the laser beam is in accordance with the length direction of the channel of the poly silicon semiconductor layer 45 to be formed in the following step 7. The scan direction of the laser beam is perpendicular to the length direction of the channel of the poly silicon semiconductor layer 45 to be formed in the following step 7. The amorphous silicon layer 3 absorbs the energy of the laser beam and the temperature is raised to melt to recrystallize. Because the convex part 21 is thicker and the heat conservation is better. The temperature of the amorphous silicon layer 3 in the convex part 21 is higher and melts more completely; the concave part 23 is thinner and the heat conservation is worse. The temperature of the amorphous silicon layer 3 in the concave part 23 is relatively lower and the melting down is not so complete. Accordingly, temperature gradients exist between the convex part 21 and the concave part 23. The recrystallization of the amorphous silicon occurs in accordance with the directions from low energy toward high energy, from low temperature to high temperature. Therefore, the amorphous silicon in the concave part 23 which the temperature is relatively lower starts to crystallize, and then the recrystallization occurs along the direction from the low temperature to the high temperature, i.e. along the direction from the concave part 23 toward the convex part 21. Ultimately, the crystal lattices meet in the middle of the length direction of the channel. Accordingly, the locations and the directions of the recrystallization of the amorphous silicon layer 3 as forming a poly silicon layer 4 can be effectively controlled. The amount of grain boundaries in the channel area can be reduced to make the distribution of the crystallization on the entire substrate more uniform.

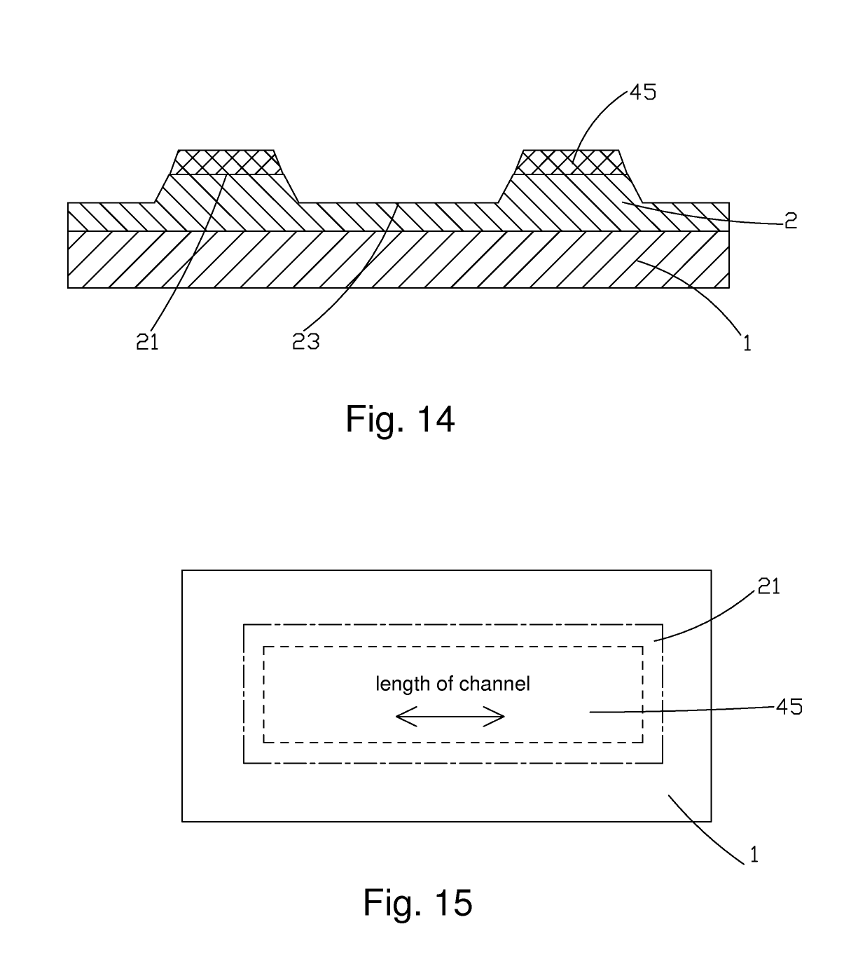

step 7, as shown in FIG. 14, FIG. 15, implementing formation treatment to the poly silicon layer 4 to form a poly silicon semiconductor layer 45.

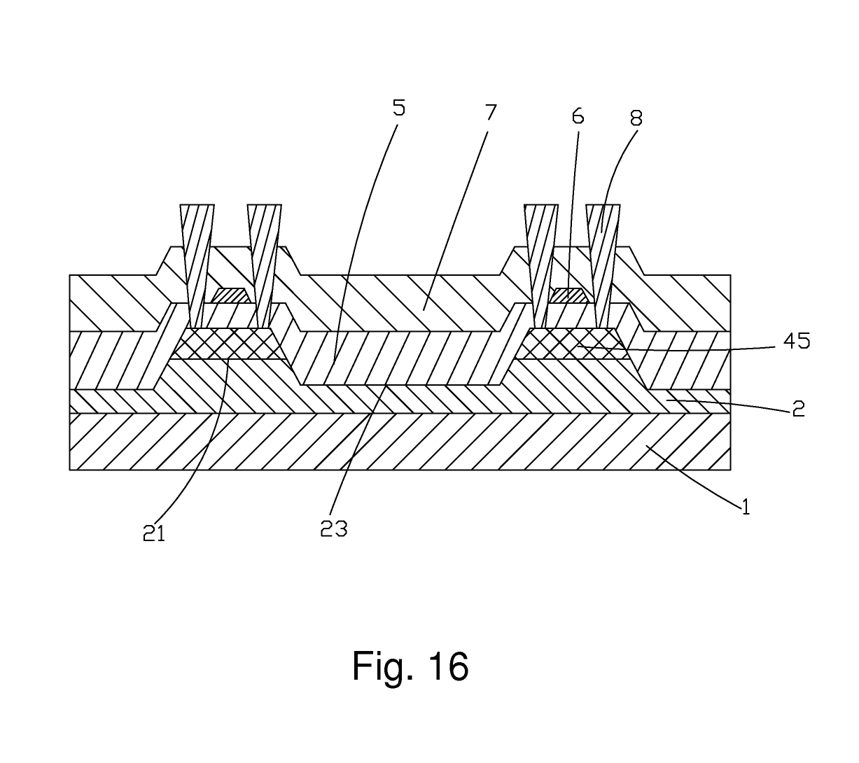

step 8, as shown in FIG. 16, sequentially forming a gate isolation layer 5, a gate 6, an isolation layer 7, a source/a drain 8 on the poly silicon semiconductor layer 45, and the source/the drain 8 is connected to the poly silicon semiconductor layer 45.

The present invention further provides a TFT substrate structure utilizing the manufacture method of a TFT substrate. Please refer to FIG. 16, the substrate structure comprises: a substrate 1, a buffer layer 2 on the substrate 1, a poly silicon semiconductor layer 45 on the buffer layer 2, and the buffer layer 2 comprises the convex part 21 and the concave part 23 having different thicknesses.

The locations and the directions of the crystallization during the formation of the poly silicon semiconductor layer 45 on the buffer layer 2 can be effectively controlled to reduce the amount of grain boundaries in the channel area to provide higher electron mobility to raise the performance of the TFT substrate and to promote the display effect because the buffer layer 2 comprises convex part 21 and the concave part 23 having different thicknesses.

The TFT substrate structure further comprises a gate isolation layer 5 on the poly silicon semiconductor layer 45 and the buffer layer 2, a gate 6 on the gate isolation layer 5, an isolation layer 7 on the gate 6 and the gate isolation layer 5 and a source/a drain 8 on the isolation layer 7, and the source/the drain 8 is connected to the poly silicon semiconductor layer 45.

The orientation of the convex part 21 and the concave part 23 corresponds to an orientation of a length direction of a channel of the poly silicon semiconductor layer 45.

A thickness difference between the convex part 21 and the concave part 23 is larger than 500 A.

The material of the buffer layer 2 is SiNx, SiOx, or a combination of the SiNx and the SiOx.

In conclusion, the manufacture method of Low Temperature Poly Silicon forms the convex part and the concave part having different thicknesses by patterning the buffer layer. In the excimer laser anneal process, the heat conservation of the convex part is better than that of the concave part. Accordingly, a temperature gradient is formed for effectively controlling the locations and the directions of the recrystallization of the amorphous silicon layer as forming a poly silicon layer to make the distribution of the crystallization on the entire substrate more uniform. The method is simple and easy for operation. The manufacture method of a TFT substrate by utilizing the manufacture method of Low Temperature Poly Silicon forms the convex part and the concave part having different thicknesses by patterning the buffer layer. In the excimer laser anneal process, the heat conservation of the convex part is better than that of the concave part. Accordingly, a temperature gradient is formed for effectively controlling the locations and the directions of the recrystallization of the amorphous silicon layer as forming a poly silicon layer to reduce the amount of grain boundaries in the channel area to make the distribution of the crystallization on the entire substrate more uniform for raising the performance of the TFT substrate. According to the substrate structure utilizing the manufacture method of a TFT substrate, the buffer layer comprises convex part and the concave part having different thicknesses. Accordingly, the locations and the directions of the crystallization during the formation of the poly silicon semiconductor layer on the buffer layer can be effectively controlled to reduce the amount of grain boundaries in the channel area to provide higher electron mobility to raise the performance of the TFT substrate and to promote the display effect.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A manufacture method of Low Temperature Poly Silicon, comprising steps of:
step 1, providing a substrate;
step 2, depositing a buffer layer on the substrate;
step 3, patterning the buffer layer to form a convex part and a concave part having different thicknesses;
step 4, depositing an amorphous silicon layer on the buffer layer comprising the convex part and the concave part;
step 5, implementing a pretreatment of an excimer laser anneal to the amorphous silicon layer;
step 6, implementing the excimer laser anneal to the amorphous silicon layer, and a laser beam scans an entire surface of the amorphous silicon layer to melt the amorphous silicon layer to recrystallize as a poly silicon layer.

2. The manufacture method of Low Temperature Poly Silicon according to claim 1, wherein material of the buffer layer is SiNx, SiOx, or a combination of the SiNx and the SiOx.

3. The manufacture method of Low Temperature Poly Silicon according to claim 1, wherein an orientation of the convex part and the concave part in the third step is in accordance with an orientation of the laser beam and perpendicular to a scan direction of the laser beam in the sixth step; the orientation of the convex part and the concave part in the third step corresponds to a length direction of a channel of the poly silicon semiconductor layer to be formed.

4. The manufacture method of Low Temperature Poly Silicon according to claim 1, wherein a thickness difference between the convex part and the concave part is larger than 500 A; the amorphous silicon layer melts to recrystallize as the poly silicon layer in the sixth step, and the amorphous silicon layer of the concave part crystallizes first and then recrystallization occurs along a direction from the concave part to the convex part.

5. A manufacture method of a TFT substrate, comprising steps of:
step 1, providing a substrate;
step 2, depositing a buffer layer on the substrate;
step 3, patterning the buffer layer to form a convex part and a concave part having different thicknesses;
step 4, depositing an amorphous silicon layer on the buffer layer comprising the convex part and the concave part;
step 5, implementing a pretreatment of an excimer laser anneal to the amorphous silicon layer;
step 6, implementing the excimer laser anneal to the amorphous silicon layer, and a laser beam scans an entire surface of the amorphous silicon layer to melt the amorphous silicon layer to recrystallize as a poly silicon layer;
step 7, implementing formation treatment to the poly silicon layer to form a poly silicon semiconductor layer;
step 8, sequentially forming a gate isolation layer, a gate, an isolation layer, a source/a drain on the poly silicon semiconductor layer, and the source/the drain is connected to the poly silicon semiconductor layer.

6. The manufacture method of Low Temperature Poly Silicon according to claim 5, wherein material of the buffer layer is SiNx, SiOx, or a combination of the SiNx and the SiOx.

7. The manufacture method of Low Temperature Poly Silicon according to claim 5, wherein an orientation of the convex part and the concave part in the third step is in accordance with an orientation of the laser beam and perpendicular to a scan direction of the laser beam in the sixth step; the orientation of the convex part and the concave part in the third step corresponds to a length direction of a channel of the poly silicon semiconductor layer formed in the seventh step.

8. The manufacture method of Low Temperature Poly Silicon according to claim 5, wherein a thickness difference between the convex part and the concave part is larger than 500 A; the amorphous silicon layer melts to recrystallize as the poly silicon layer in the sixth step, and the amorphous silicon layer of the concave part crystallizes first and then recrystallization occurs along a direction from the concave part to the convex part.

9. A TFT substrate structure, comprising a substrate, a buffer layer on the substrate, a poly silicon semiconductor layer on the buffer layer, a gate isolation layer on the poly silicon semiconductor layer and the buffer layer, a gate on the gate isolation layer, an isolation layer on the gate and the gate isolation layer and a source/a drain on the isolation layer, and the source/the drain is connected to the poly silicon semiconductor layer, wherein the buffer layer comprises the convex part and the concave part having different thicknesses.

10. The TFT substrate structure according to claim 9, wherein an orientation of the convex part and the concave part corresponds to a length direction of a channel of the poly silicon semiconductor layer, and a thickness difference between the convex part and the concave part is larger than 500 A, and material of the buffer layer is SiNx, SiOx, or a combination of the SiNx and the SiOx.
